(19) United States
(12) Patent Application Publication
(10) Pub. No.: US 2014/0201583 A1
(43) Pub. Date: Jul. 17, 2014

(54) System and Method For Non-Intrusive Random Failure Emulation Within an Integrated Circuit

(71) Applicant: Mathieu Thomas, Vence (FR)

(72) Inventor: Mathieu Thomas, Vence (FR)

(73) Assignee: Scaleo Chip, Valbonne (FR)

(21) Appl. No.: 13/742,161

(22) Filed: Jan. 15, 2013

(51) Int. Cl. G01R 31/3177

(52) U.S. Cl. CPC G01R 31/3177
USPC 714/727

(57) ABSTRACT

The apparatus and methods allow random hardware failure emulation of an integrated circuit (IC) by emulation of potential defects to enable behavior evaluation of the rest of the design in such situation. This emulation can non-intrusively address multiple points of failure. The emulation is performed in a pseudo-functional mode in order to evaluate the IC behavior in its standard functional mode. The system allows creation of a failure, and tracking both the detection of this failure and the required time for this detection. The system further allows generation of a failure in different points of the IC, on a single or multipoint failure approaches. Failure detection and correction mechanisms for a product life cycle are therefore provided. In an embodiment the system checks the conformity of the safety function of an IC, and makes sure the safety control logic behaves as expected in case of data corruption in any register.

### BACKGROUND OF THE INVENTION

1. Field of the Invention

The invention generally relates to emulation of random failures within an integrated circuit (IC) and more particularly to detection and validation thereof.

2. Prior Art

Failure detection and correction mechanisms that are integrated within an integrated circuit (IC), aim to deal with malfunctions that randomly appear during the IC life cycle. Since such failure occurs randomly, there is no direct way to test that those embedded mechanisms work as expected on silicon. It would therefore be advantageous to provide a solution to overcome the problem.

Various techniques may be used to provide the fault or error detection, depending on the function of the IC and its application. In some cases, a duplicate circuit may be incorporated on chip, with a comparison of the outputs or intermediate results showing the occurrence of an error or fault. In other cases, errors or faults may be detected by an irregularity in the results provided by the IC, such as by exceeding a maximum allowed incremental change between successive outputs. In still other cases, error detection and correction codes may be used. In practice, in any one IC, a number of different techniques for error detection may be incorporated, as use of any one technique generally does not preclude use of another technique on the same chip. Various specific techniques that may be used on chip are well known, and not the subject of the present invention, other than at least one such technique be present on chip.

Another test technique is to incorporate what is commonly referred to as scan chains, wherein registers in the IC can be temporarily coupled in series by on chip switches so that the registers may be tested by clocking various test data patterns through the chain and comparing the output of the chain with its input. Such a technique will quickly show a bad flip flop, and using a variety of test data patterns, will also show any cross talk between flip flops. This technique does not test the function of the error detection/error detection and correction provided on chip.

### BRIEF DESCRIPTION OF THE DRAWINGS

The subject matter that is regarded as the invention is particularly pointed out and distinctly claimed in the claims at the conclusion of the specification. The foregoing and other objects, features and advantages of the invention will be apparent from the following detailed description taken in conjunction with the accompanying drawings.

FIG. 1 is a schematic block diagram of a portion of an integrated circuit(IC) according to an embodiment.

FIG. 2 is a detailed block diagram of a failure emulation system on register apparatus of an IC according to an embodiment.

FIG. 3 is a detailed block diagram of a data corruption module apparatus of an IC according to an embodiment.

### DETAILED DESCRIPTION OF THE PREFERRED EMBODIMENTS

It is important to note that the embodiments disclosed by the invention are only examples of the many advantageous uses of the innovative teachings herein. In general, statements made in the specification of the present application do not necessarily limit any of the various claims. Moreover, some statements may apply to some inventive features but not to others. In general, unless otherwise indicated, singular elements may be in plural and vice versa with no loss of generality. In the drawings, like numerals refer to like parts through several views.

The present invention is used to demonstrate and/or improve the safety of IC embedded in domains such as automotive or avionics where compliance of the electronics with safety norms (such as ISO26262 for automotive or DO254 for avionics) is more and more requested by final customers. According to the invention a failure injection is enabled and the detection of the failure allows demonstration of the safety feature embedded in the IC and the compatibility of the IC to a safety standard. Other applications may include space vehicles and medical applications wherein an undetected failure of the IC may risk the success of the mission or death of a patient, particularly if not detected either before the critical use or during use of the IC.

The apparatus and methods allow random hardware failure emulation of an integrated circuit (IC) by emulation of potential defects to enable behavior evaluation of the rest of the design in such situation. This emulation can non-intrusively address multiple points of failure. The emulation is performed in a pseudo-functional mode in order to evaluate the IC behavior in its standard functional mode. The system allows creation of a failure, and tracking both the detection of this failure and the required time for this detection. The system further allows generation of a failure in different points of the IC, on a single or multipoint failure approaches. Failure detection and correction mechanisms for a product life cycle are therefore provided. In an embodiment the system checks the conformity of the safety function of an IC, and makes sure the safety control logic behaves as expected in case of data corruption in any register.

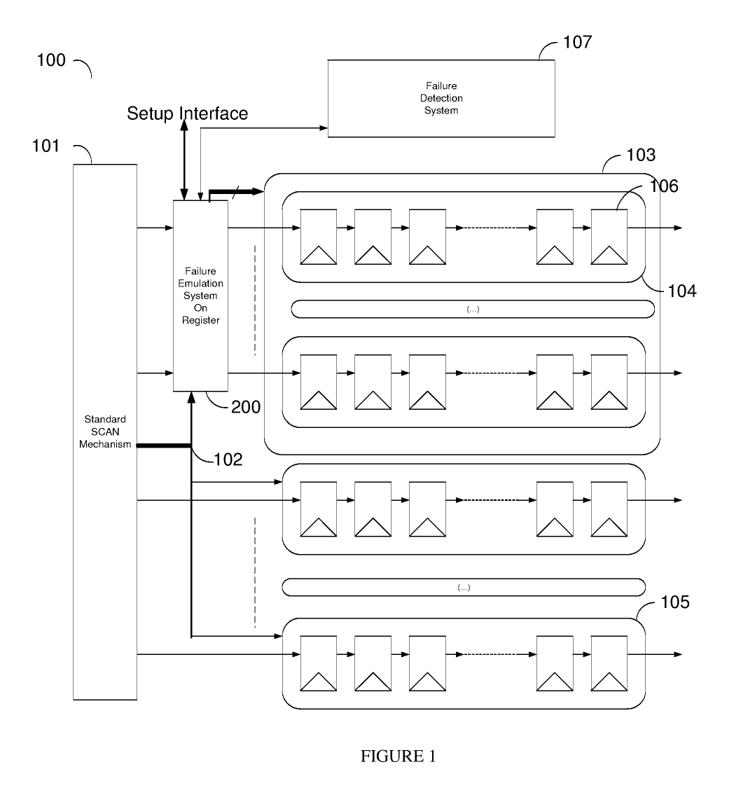

FIG. 1 is an exemplary and non-limiting schematic block diagram 100 of a portion of an IC according to an embodiment. The IC is typically implemented on a monolithic semiconductor device. A standard SCAN is implemented for the IC in order to catch potential manufacturing defects. The SCAN architecture is composed of scan chains, such as the scan chain 105, that are controlled through various standard SCAN mechanisms 101, which are well known in the industry and are outside the scope of the invention.

A failure emulation system on register apparatus 200 is configured to turn part of the overall scan chains 103 of the system to scan mode while the rest of the system works in functional mode which includes its error detection capability. The apparatus 200 takes control of the scan enable signals 102 and propagates dummy values (one or more corrupted values in otherwise functional data) along the corresponding scan chain, such as the scan chain 104 that is part of the overall scan chains 103, in order to corrupt the functional data that is stored, for example, in register 106. Failure detection system (FDS) 107, which is embedded in the system 100, and is outside of the scope of the invention, detects the data corruption according to well-known principles of operation. Thus individual scan chains may be enabled while the registers of associated with the other scan chains may remain in their respective functional mode.

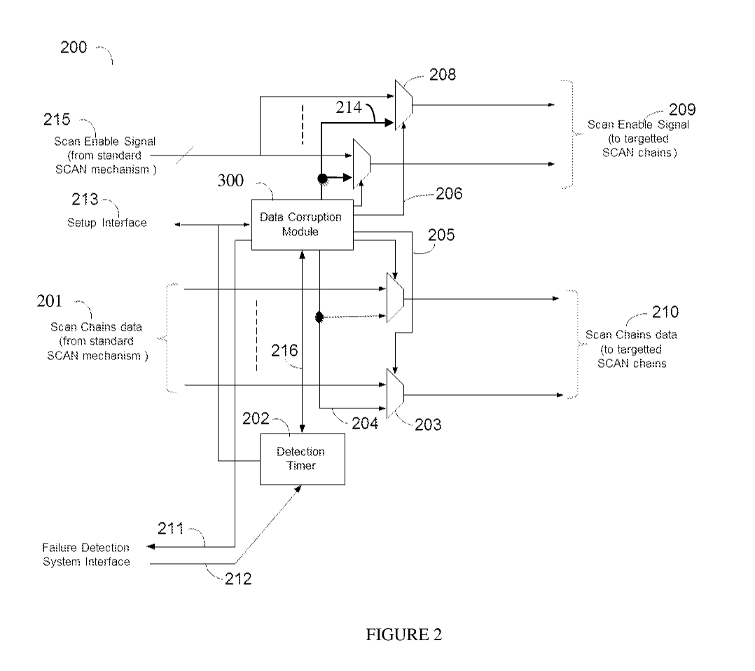

FIG. 2 is an exemplary and non-limiting detailed block diagram of the apparatus 200. A setup interface 213 allows controlling the failure emulation function. Setup interface 213 allows choosing the scan chains where a failure will be emulated, and the sort of data corruption which will be made. The data corruption module (DCM) 300, described in greater detail herein below, is in charge of the corruption of the data through the scan chain. This corruption can be made, for example, through a pseudo random pattern generator. It may be started, for example, immediately after a request is received through setup interface 213, or at a random time. When the data corruption starts, a signal is used, on the failure detection system interface (FDSI) 211, to provide any information to the IC as may be required. In order to perform the corruption of the data, the DCM 300 turns the required scan chain to shift mode using multiplexer 208. The scan enable signal 215, which allows switching the required chain to shift mode, is provided from a specific scan enable signal 214 which is controlled by DCM 300 and propagated to the targeted scan chains through scan enable signal interface 209. Signal 206 allows determining which scan chain is used for the data corruption though multiplexer 208. Signal 205 ensures the shift of the corruption data 204 through the appropriated scan chain using multiplexer 203. One of ordinary skill-in-the-art would readily appreciate that as a result the scan chains data 201 is no longer provided from a standard scan mechanism 101, but rather from the DCM 300 through the dedicated scan interface 210.

The system 200 allows the scan chains which are candidates for corruption to be used in shift mode while the rest of the design remains in functional mode. The system 200 may include a detection timer 202. Detection timer 202 may measure the time between the start of corruption and its detection through the FDS 107. Detection timer 202 has an interface 216 with DCM 300. The detection timer 202 is implemented through a counter running with respect of a reference clock. Interface 216 enables the counter to initialize when the corruption starts, and stopping the data corruption when the failure emulation is detected. A dedicated signal 212 of the FDSI 211 indicates to the system when the emulated fault has been detected. Then, the time elapsed between the fault emulation and its catching can be read back through the Setup Interface 213.

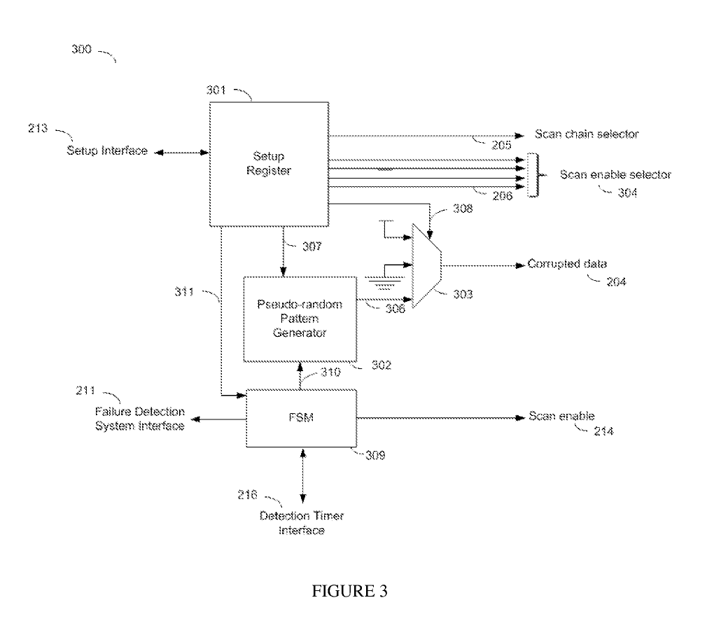

FIG. 3 is an exemplary and non-limiting detailed block diagram of the DCM 300 according to an embodiment. Through the functional setup interface 213, the setup register 301 is programmed in order to define the mode of corruption and the scan chain targeted by the data corruption process. A scan enable selector bus 304 provides a dedicated signal 206 for each targeted scan chain to determine whether the corruption should occur on this scan chain or not. The type of corruption is chosen through the multiplexer 303. Depending on the selector signal 308, the corrupted data 204 is selected between a constant low value, a constant high value, or a pseudo random value 306. This pseudo random value is provided by a pseudo-random pattern generator (PRPG) 302 that is activated by a setting within the setup register 307. Corrupted data may comprise a single corrupted bit or multiple corrupted bits. A failure state machine (FSM) 309 provides a start signal 310 so that the PRPG 302 starts the corruption of data. The FSM 309 behavior is setup through a setup signal 311. When the corruption starts, scan enable signal 214 is placed at high level value to propagate the corrupted data over the selected scan chain. At the same time, IC failure detection system 107 is informed of the start of corruption through the signal 211. The detection timer 202 starts counting through a command passed on the detection timer interface 216. When the corrupted data is detected by the FDS 107, the detection timer 202 stops counting and causes the DCM 300 to switch back into idle mode, that is, the IC is switched back into functional mode.

The principles of the invention are implemented as hardware or a combination of hardware, firmware, and software of any combination. With respect of firmware and software these are preferably implemented as an application program tangibly embodied on a program storage unit or computer readable medium. The application program may be uploaded to, and executed by, a machine comprising any suitable architecture. Preferably, the machine is implemented on a computer platform having hardware such as one or more central processing units (“CPUs”), a memory, and input/output interfaces. The computer platform may also include an operating system and microinstruction code. The various processes and functions described herein may be either part of the microinstruction code or part of the application program, or any combination thereof, which may be executed by a CPU, whether or not such computer or processor is explicitly shown. In addition, various other peripheral units may be connected to the computer platform such as an additional data storage unit and a printing unit and/or display unit. An IC includes, also and without limitation a system on chip (SoC). The IC may be implemented as a monolithic semiconductor device.

Thus the present invention uses existing test features (SCAN or BIST) to improve the safety of an IC in functional mode by injecting a fault (corrupted data) to validate that the safety mechanism is able to detect it, and when it is detected in comparison to the time the fault was simulated. As an example, the prior art section mentioned that some ICs include redundancy for safety purpose, that is, they embed the same function twice, such as in the case of a processor, to allow the application comparing the results obtained to detect a failure in the system. Using the present invention, the output of some registers of one of the two processors may be modified, which will emulate a failure in the given processor. This will produce a wrong result that has to be detected. By injecting a fault, the user is able to check that the safety feature is working. This can be used to validate the safety procedures in an initialization phase (e.g. in an aircraft application, before the plane leaves, the pilot can check the safety features to ensure a failure detection during the flight). The delay between the fault injection and the error detection may also be important, both as an indication of which fault detection mechanism caught the error, but also to indicate whether unsatisfactory consequences can result from such an error before automatically switching to a backup or a manual system.

All examples and conditional language recited herein are intended for pedagogical purposes to aid the reader in understanding the principles of the invention and the concepts contributed by the inventor to furthering the art, and are to be construed as being without limitation to such specifically recited examples and conditions. Moreover, all statements herein reciting principles, aspects, and embodiments of the invention, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

What is claimed is:

1. An integrated circuit (IC) comprising:
a plurality of scan chains;
a scan mechanism coupled to the plurality of scan chains to provide functional data into the plurality of scan chains;
a failure detection system configured to detect failures of the IC respective of the functional data; and
a failure emulation system on register coupled to the scan mechanism and at least one scan chain of the plurality of scan chains, the failure emulation system on register being configured to inject corrupted data into the at least one scan chain by providing corrupted data in place of the functional data;
wherein the failure detection system generates a failure indication responsive to the detection of the corrupted data.

2. The IC of claim 1, wherein the failure emulation system on register is configured to provide the at least one scan chain with one of: the functional data or the corrupted data.

3. The IC of claim 1, wherein the failure emulation system on register further comprises:
a detection timer.

4. The IC of claim 3, wherein the detection timer begins counting upon insertion of the corrupted data.

5. The IC of claim 4, wherein the detection timer ceases counting upon detection of a failure by the failure detection system.

6. The IC of claim 1, wherein the IC is implemented on a monolithic semiconductor device.

7. The IC of claim 1, wherein the IC comprises a system on chip.

8. A failure emulation system on register for an integrated circuit (IC), the failure emulation system comprising:
an interface to a scan mechanism of the IC;
an interface to at least a scan chain of the IC; and
a data corruption module coupled to the interface and to at least a scan chain, the data corruption module configured to provide corrupted data that is injected into the at least a scan chain.

9. The failure emulation system on register of claim 8, further comprising:
a multiplexer connected to the interface to the at least a scan chain configured to provide to the scan chain one of: corrupted data, functional data provided from a scan mechanism of the IC.

10. The failure emulation system on register of claim 8, further comprises:
a detection timer.

11. The failure emulation system on register of claim 10, wherein the detection timer begins counting upon insertion of the corrupted data.

12. The failure emulation system on register of claim 10, wherein the detection timer ceases counting upon detection of a failure by the data corruption module.

13. The failure emulation system on register of claim 8, wherein the failure emulation system on register is implemented on a monolithic semiconductor device.

14. The failure emulation system on register of claim 8, wherein the IC is a system on chip.
